(19) United States
(12) Patent Application Publication
(10) Pub. No.: US 2026/0051461 A1
(43) Pub. Date: Feb. 19, 2026

(54) SYSTEMS AND METHODS FOR BEVEL DEPOSITION

(71) Applicant: APPLIED MATERIALS, INC., Santa Clara, CA (US)

(72) Inventors: Dmitry Lubomirsky, Cupertino, CA (US); Pranav Vijay Gadre, Sunnyvale, CA (US); Hyun Joo Lee, Seoul (KR); Douglas Arthur Buchberger, JR., Livermore, CA (US); Adib Mahmood Newaz Khan, San Jose, CA (US); Qiwei Liang, Fremont, CA (US); Hyunjun Kim, Campbell, CA (US); Shekhar Athani, Bengaluru (IN); Srinivas Durgaprasad Nemani, Saratoga, CA (US); Ellie Yi-Li Yieh, San Jose, CA (US)

(21) Appl. No.: 18/805,184

(22) Filed: Aug. 14, 2024

(51) Int. Cl. H01J 37/32; C23C 16/455; H01L 21/02

(52) U.S. Cl. CPC H01J 37/32449; C23C 16/45565; H01J 37/32715; H01J 37/32082; H01J 2237/2007; H01J 2237/20214; H01J 2237/20235; H01J 2237/3321; H01L 21/02274

(57) ABSTRACT

A system includes a process chamber, a substrate support assembly to support a substrate, and a shower head assembly. The shower head assembly includes a gas distribution plate including an inner region having a first radius and a first thickness and an outer region, that is concentric with the inner region, having a f second radius that is greater than the first radius. The outer region further having a second thickness that is less than the first thickness causing the inner region to have a first distance from the substrate and the outer region to have a second distance from the substrate. The first distance is less than the second distance. The gas distribution plate is configured to deposit a coating on an outer region of the substrate without depositing the coating on an inner region of the substrate.

### TECHNICAL FIELD

The present disclosure generally relates to systems and methods for deposition in electronics manufacturing. More particularly, the present disclosure relates to systems and methods for bevel deposition in electronics manufacturing.

### BACKGROUND

Manufacturing processes can involve the use of deposition chambers to deposit thin films on substrates (e.g., such as semiconductor wafers, glass panels, etc.) during deposition processes. The accuracy and uniformity of deposition processes can influence the quality and reliability of the manufactured semiconductor devices.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a system includes a process chamber, a substrate support assembly disposed within a process volume of the process chamber to support a substrate, a shower head assembly disposed within the process volume of the process chamber. The shower head assembly includes a gas distribution plate. The gas distribution plate includes an inner region having a first radius and a first thickness, wherein the first thickness causes the inner region to have a first distance from the substrate. The gas distribution plate further includes an outer region that is concentric with the inner region, the outer region having a second radius that is greater than the first radius, the outer region further having a second thickness that is less than the first thickness. The second thickness causes the outer region is configured to have a second distance from the substrate. The first distance is less than the second distance. The gas distribution plate is configured to deposit a coating on an outer region of the substrate while mitigating deposition of the coating on an inner region of the substrate.

In another aspect of the disclosure, a method includes flowing a process gas through a first flow path of a shower head assembly of a chemical vapor deposition chamber to perform chemical vapor deposition of a coating on an outer region of a substrate. The method further includes flowing a purge gas through a second flow path of the shower head assembly to prevent deposition of the coating on an inner region of the substrate.

In another aspect of the disclosure, a system includes a process chamber, a substrate support assembly disposed within a process volume of the process chamber to support a substrate, and a shower head assembly disposed within the process volume of the process chamber. The shower head assembly includes a gas distribution plate including an inner region having a first radius and a first thickness, wherein the first thickness causes the inner region to have a first distance from the substrate. The gas distribution plate further includes an outer region that is concentric with the inner region, the outer region having a second radius that is greater than the first inner radius, the outer region further having a second thickness that is less than the first thickness. The second thickness causes the outer region to have a second distance from the substrate. The first distance is less than the second distance. The gas distribution plate including the inner region and the outer region is configured to deposit a coating on an outer region of the substrate while mitigating depositing the coating on an inner region of the substrate. The system further includes a controller to flow a process gas through a first flow path of the shower head assembly to perform chemical vapor deposition of a coating on an outer region of the substrate. The controller is further to flow a purge gas through a second flow path of the shower head assembly to prevent deposition of the coating on an inner region of the substrate.

### BRIEF DESCRIPTION OF THE DRAWINGS

The present disclosure is illustrated by way of example, and not by way of limitation in the figures of the accompanying drawings.

FIG. 1A depicts a cross-sectional side view of a processing chamber, according to some embodiments.

FIG. 1B depicts a cross-sectional side view of a processing chamber, according to some embodiments.

FIG. 2A depicts a cross-sectional view of a bevel deposition of a substrate, according to some embodiments.

FIG. 2B depicts a top view of a bevel deposition of a substrate, according to some embodiments.

FIG. 3 is a flow diagram of a method associated with bevel deposition on a substrate, according to some embodiments.

FIG. 4 is a block diagram illustrating a computer system, according to some embodiments.

### DETAILED DESCRIPTION

In semiconductor manufacturing, a semiconductor manufacturing system includes manufacturing equipment that is used to perform various recipes and process steps on substrates (e.g., wafers) to manufacture electronic devices. Maintaining the integrity and quality of wafer surfaces, particularly near the edges or bevels, helps to ensure high yields and to maintain consistent performance of the manufactured devices.

The bevel of a substrate, such as a wafer, can be prone to defects. These defects can propagate from the bevel towards the center of the wafer, potentially compromising the wafer's functionality and the overall yield of manufactured devices. To mitigate these issues, bevel deposition techniques are employed in embodiments to deposit protective layers, such as silicon oxide (SiO), silicon nitride (SiN), or silicon carbonitride (SiCN), concentrically on the front side bevel of the wafer. In embodiments, the protective layers are deposited on the outer perimeter (e.g., bevel) of the substrate (e.g., of a wafer) with reduced or minimal deposition of the protective layers elsewhere on the substrate. In some embodiments, the protective layers are deposited on the outer perimeter (e.g., bevel) of the substrate (e.g., of a wafer) without depositing the protective layers elsewhere on the substrate. This process helps to reduce edge defects and prevents edge defects from extending into the active regions of the substrate, improving overall yield and reliability. Additionally, for wafer bonding applications, applying a bevel film assists in closing gaps near the edges of bonded wafers, enhancing bond quality and structural integrity.

Conventional methods for bevel deposition in semiconductor manufacturing, such as chemical vapor deposition (CVD) and physical vapor deposition (PVD), apply thin protective films across the wafer's surface. Accordingly, conventional bevel deposition results in deposition on the wafer's center and/or backside, leading to contamination and process interference. Available process chambers lack for the capability of depositing uniform and concentric deposition of films on only the outer perimeter (e.g., bevel) of a wafer or other substrate. Consequently, these traditional approaches to bevel protection result in unintended central and backside deposition and non-uniform film application, which complicates device fabrication, interferes with wafer bonding, and negatively impacts the electrical properties and reliability of manufactured devices.

Aspects and implementations of the present disclosure address these challenges by providing systems and methods for bevel deposition on substrates. For example, a process chamber (e.g., a plasma enhanced chemical vapor deposition chamber) includes a substrate support assembly to hold a substrate, such as a wafer. The process chamber also includes a shower head assembly. The shower head assembly can be RF biased with at least a portion of the substrate support assembly being grounded. When a process gas is flowed through the shower head these RF biased components act as electrodes creating a process plasma that can enhance deposition efficiency and improve film quality.

The shower head assembly includes a gas distribution plate (e.g., a faceplate) having both an inner and outer region that are concentric and each have a different thickness. The difference in thickness between the inner and outer region results in the inner region being in close proximity to the substrate while the outer region is farther from the substrate. Because of the difference in thickness between the two regions, when a process gas is flowed through the shower head a coating (e.g., a film deposition) is selectively applied to the outer region (e.g., outer perimeter or bevel) of the substrate while avoiding deposition on the inner region. In some embodiments, because the inner region of the gas distribution plate is in close proximity to the substrate, plasma formation is inhibited at an inner region of the substrate. However, the increased distance between the outer region of the gas distribution plate and the substrate creates a larger volume where plasma ignition is not inhibited, resulting in plasma enhanced chemical vapor deposition on a target region near the edge of the substrate.

To further tune the radius of the bevel deposition and to ensure that the coating is not deposited on the inner region of the substrate, the shower head assembly may also include separate flow paths to deliver a purge gas to the inner region of the substrate and a process gas to the outer region of the substrate. A flow controller can adjust a ratio of the purge gas flow rate to the process gas flow rate to control the size of the outer region where the coating is applied. A substrate support assembly (e.g., a pedestal of the substrate support assembly) can also be adjusted vertically to adjust the distances between the regions of the gas distribution plate and substrate (e.g., to inhibit or promote plasma ignition). Additionally, vertical adjustment of the substrate support pedestal allows for loading and unloading of substrates.

The substrate support assembly can further be configured to chuck (e.g., hold) the wafer securely during processing. Chucking can also eliminate bowing of the substrate to improve deposition uniformity and concentricity. The substrate support assembly (e.g., pedestal) can also be rotated during a deposition process to improve uniformity (e.g., radial uniformity) and concentricity of the bevel deposition.

Aspects and implementations of the present disclosure can help to maintain the integrity and quality of substrate surfaces near the edges or bevels by enabling concentric and uniform bevel deposition. By enabling concentric and uniform bevel deposition, aspects and implementations of the present disclosure can prevent defects at or near the edge of the substrate from propagating towards the center of the substrate, improving the substrate's functionality and the overall yield of manufactured devices. Aspects and implementations of the present disclosure can eliminate unintended deposition on the substrate's center and backside, reducing contamination and process interference.

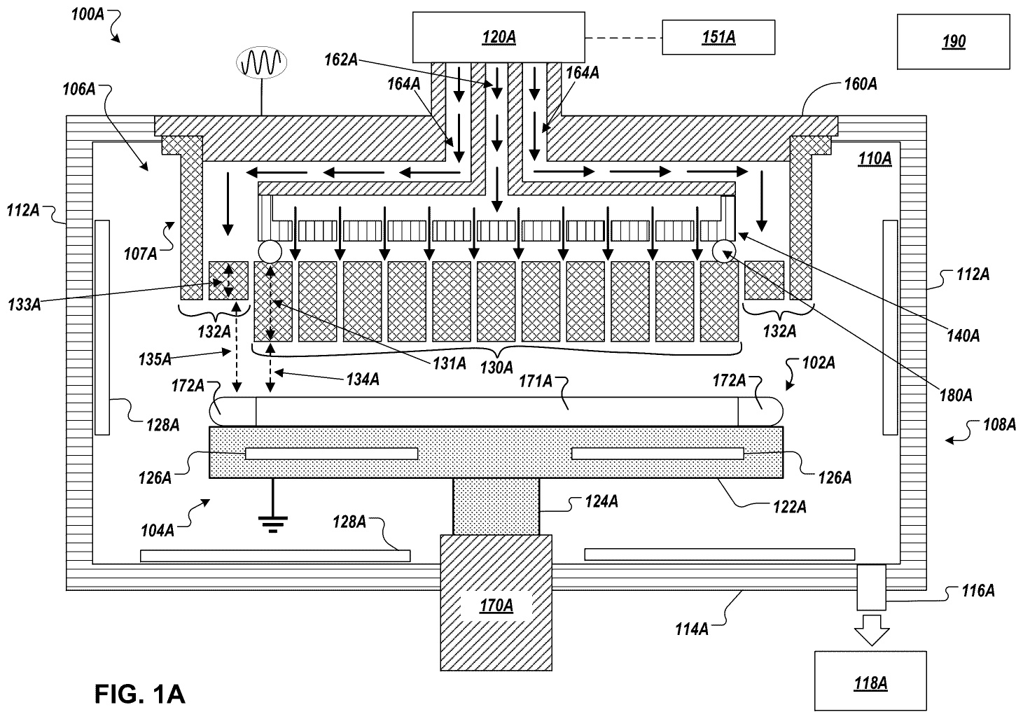

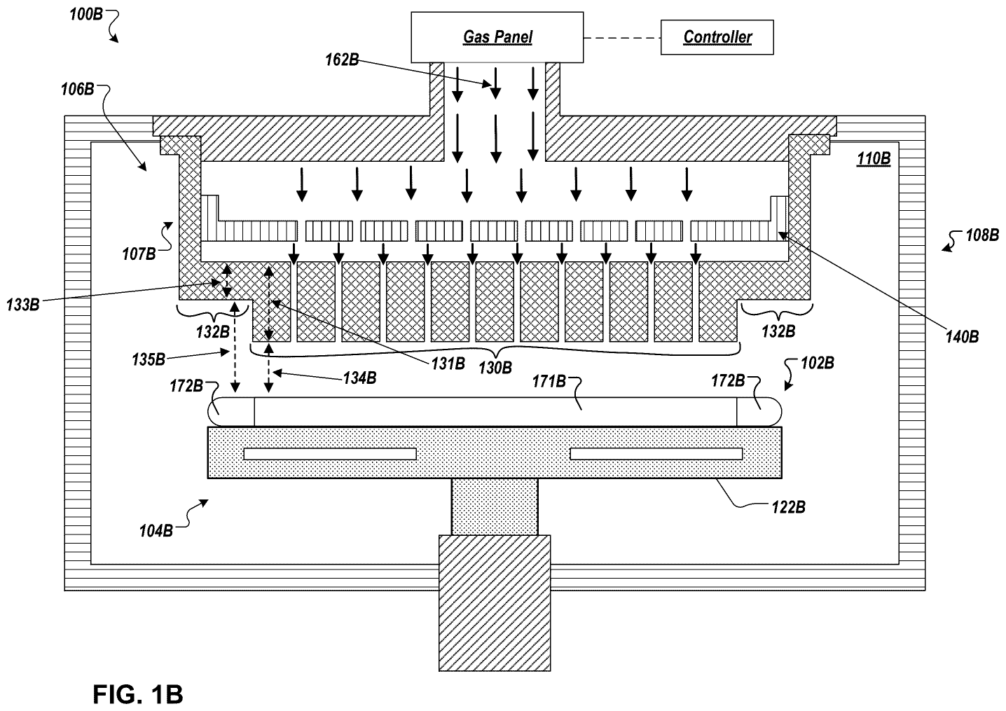

FIG. 1A depicts a sectional view of a manufacturing chamber 100A (e.g., a plasma enhanced chemical vapor deposition chamber), according to some aspects of this disclosure. Manufacturing chamber 100A may be a deposition chamber (including atomic layer deposition, chemical vapor deposition, physical vapor deposition, or plasma enhanced versions thereof). For example, manufacturing chamber 100A may be a chamber for a plasma enhanced chemical vapor deposition device. Examples of chamber components may include a substrate support assembly 104A (e.g., which may include an electrostatic chuck), a ring (e.g., a process kit ring), a chamber wall, a base, a showerhead assembly 106A (e.g., which may include one or more gas distribution plates, such as a stack of three gas distribution plates), a liner, a liner kit, a shield, a plasma screen, a flow equalizer, a cooling base, a chamber viewport, a chamber lid, a nozzle and so on.

In one embodiment, manufacturing chamber 100A may include a chamber body 108A and a showerhead assembly 106A that enclose an process volume 110A. Chamber body 108A may be constructed from aluminum, stainless steel, or other suitable material. Chamber body 108A generally includes sidewalls 112A and a bottom 114A.

An exhaust port 116A may be defined in chamber body 108A and may couple process volume 110A to a pump system 118A. Pump system 118A may include one or more pumps and valves utilized to evacuate and regulate the pressure of process volume 110A of manufacturing chamber 100A. An actuator to control gas flow out of the chamber and/or pressure in the chamber may be disposed at or near exhaust port 116A.

Shower head assembly 106A may be supported on sidewalls 112A of chamber body 108A or on a top portion of the chamber body. Shower head assembly 106A may be opened to allow access to process volume 110A of manufacturing chamber 100A and may provide a seal for manufacturing chamber 100A while closed.

Shower head assembly 106A may include a first gas distribution plate 107A. First gas distribution plate 107A has an inner region 130A having a first radius (e.g., a first outer radius) and a first thickness 131A. The first thickness 131A causes the inner region 130A to be positioned a first distance 134A from a substrate 102A (e.g., supported by substrate support assembly 104A). First gas distribution plate 107A includes an outer region 132A that is concentric with the inner region 130A. The outer region includes a second radius (e.g., a second outer radius) that is greater than the first radius. The outer region 132A may have an inner radius that corresponds to the first radius of the inner region 130A in embodiments. The second radius may be greater than the inner radius in embodiments. The outer region 132A further has a second thickness 133A that is less than the first thickness 131A. The second thickness 133A causes the outer region 132A to have a second distance 135A from the substrate 102A, the first distance 134A being less than the second distance 135A. The first gas distribution plate 107A (including the inner region 130A and the outer region 132A) is configured to deposit a coating on an outer region 172A of the substrate 102A while mitigating deposition of the coating on an inner region 171A of the substrate 102A (e.g., to cause a reduced or minimal deposition of the coating on the inner region 171A). For example, in some embodiments a small amount of the coating is deposited on the inner region 171A. In some embodiments, no amount of the coating is deposited on the inner region 171A.

Showerhead assembly 106A may include a stack of multiple gas distribution plates, including for example first gas distribution plate 107A, second gas distribution plate 140A, and third gas distribution plate 160A. Showerhead assembly 106A may include multiple gas delivery holes throughout (e.g., first gas distribution plate 107A and a second gas distribution plate 140A). In some embodiments, gas delivery holes are included in both the inner region 130A and outer region 132A (e.g., to allow for two separate flow paths for process gas and a purge gas). In some embodiments, gas delivery holes are included in inner region 130A and not out region 132A (as illustrated and described in FIG. 1B).

Examples of process gases that may be used to process substrates in manufacturing chamber 100A may include toxic gases, non-toxic gases, or a combination thereof. For example, the processing gases may include halogen-containing gases, such as C₂F₆, SF₆, SiCl₄, HBr, NF₃, CF₄, CHF₃, F₂, Cl₂, CCl₄, BCl₃, and SiF₄, among others, and other gases such as O₂ or N₂O. Examples of carrier gases include N₂, He, Ar and other gases inert to process gases (e.g., non-reactive gases). In some embodiments, a deposition operation of process chamber 100A deposits at least one of SiOₓ, SiN, or SiCN on substrate 102A.

Showerhead assembly 106A may include second gas distribution plate 140A coupled between first gas distribution plate 107A and third gas distribution plate 160A. The second gas distribution plate 140A can be configured to evenly distribute a gas and/or plasma (e.g., a purge gas) across the surface of substrate 102A. Second gas distribution plate 140A can help to control the flow of gas by preventing direct, high-velocity streams from hitting specific areas, ensuring a more uniform gas distribution and minimizing turbulence. This contributes to consistent plasma generation and uniform deposition on the substrate.

In embodiments, shower head assembly 106A includes third gas distribution plate 160A positioned above and coupled to the second gas distribution plate 140A and first gas distribution plate 107A. The third gas distribution plate 160A is configured to receive and regulate the flow of gas into the showerhead assembly 106A. The third gas distribution plate 160A ensures a steady and controlled supply of gas to the second gas distribution plate 140A and first gas distribution plate 107A.

In some embodiments, shower head assembly 106A includes a first flow path 162A configured to deliver a purge gas to the inner region 171A of the substrate. The shower head assembly 106A further includes a second flow path 164A configured to deliver a process gas to the outer region 172A of the substrate 102A. The delivery of the purge gas to the inner region 171A of the substrate 102A prevents the process gas from entering the inner region 171A of the substrate 102A preventing unwanted deposition on the inner region 171A in embodiments.

Substrate support assembly 104A may be disposed in process volume 110A of manufacturing chamber 100A below showerhead assembly 106A. In some embodiments, substrate support assembly 104A includes a susceptor 122A and shaft 124A. Substrate support assembly 104A supports substrate 102A during processing. In some embodiments, also disposed within manufacturing chamber 100A are one or more heaters 126A and reflectors 128A. In some embodiments, heaters 126A can be disposed within susceptor 122A to maintain a target temperature of substrate 102A during processing (e.g., 750 degrees Celsius).

A gas panel 120A may be coupled to manufacturing chamber 100A to provide process gases, purge gases, and/or cleaning gases to process volume 110A through showerhead assembly 106A. The gas panel 120A may be coupled to the manufacturing chamber 100A to provide process gases, purge gases, and/or cleaning gases via one or more supply line (e.g., flow path) to the process volume 110A through showerhead assembly 106A. The gas panel 120A may include or be connected to one or more flow controller 151A. The flow controller 151A may be used adjust the flow of one or more of process gases, purge gases, and/or cleaning gases into process volume 110A.

Flow controller 151A may be coupled to one or more gas stick of gas panel 120A in embodiments. Flow controller can adjust a ratio of a purge gas flow rate through the first flow path 162A and a process gas flow rate through the second flow path 164A to adjust a size of the outer region 172A of the substrate 102A on which the coating is deposited.

In some embodiments, a flow rate of the purge gas through first flow path 162A can range from 3,000 to 10,000 standard cubic centimeters per minute (sccm). The flow rate of the purge gas can depend on the gas mass (e.g., the specific type and density of the gas being used as the purge gas affects how much gas needs to be flowed through the system).

In some embodiments, the bevel deposition is accomplished using thermal deposition techniques. In some embodiments, this can be accomplished by employing the recessed first gas distribution plate 107A. In some embodiments, the flow rates of the process gas and purge gas can be adjusted to further tune the deposition area and to preclude deposition on the inner region 171A of the substrate 102A. For example, an SiOₓ coating can be deposited through a thermal CVD process.

In some embodiments, using thermal deposition techniques for bevel deposition includes the flow rates of the process gas and purge gas can be adjusted to further tune the deposition area and to preclude deposition on the inner region 271A of the substrate 102A. For example, an SiOₓ coating can be deposited through a thermal CVD process. In some embodiments, one or more of ozone and tetraethyl orthosilicate can be used as process gases. A process pressure ranges from one Torr to 760 Torr in embodiments. The substrate 102B is maintained at a temperature above 400 degrees Celsius in embodiments. In some embodiments, the substrate 102A is vacuum chucked to the substrate support pedestal. In some embodiments, the substrate 102A may be electrostatically chucked to the substrate support pedestal. In some embodiments, the first distance 134A is less than one inch (e.g., 0.080 inches, 0.075 inches, etc.) to maintain pressure between of the purge gas one Torr to 760 Torr to keep the inner region 171A area clean from process gases.

In some embodiments, the shower head assembly 106A can be RF biased and at least a portion of the substrate support assembly (e.g., susceptor 122A) is RF grounded. In some embodiments, process chamber 100A is a plasma-enhanced chemical vapor deposition chamber (e.g., chamber 100A uses capacitively coupled plasma). In some embodiments, the shower head assembly 106A and the substrate support assembly 104A are configured to create a process plasma. For example, the showerhead assembly 106A can be configured as an RF-biased electrode, while at least a portion of the substrate support assembly 104A, such as the susceptor 122A, is RF-grounded. This configuration establishes an alternating electric field between the RF-biased showerhead assembly 104A and the RF-grounded susceptor 122A. As process gas is introduced through the showerhead assembly 106B into the process volume 110A, the alternating electric field ionizes the gas molecules, creating a plasma. The energetic ions and reactive species of the plasma enhance the chemical deposition reactions on the surface of substrate 102A, facilitating the formation of a uniform thin film.

In some embodiments, because inner region 130A is in close proximity to the substrate 102A, plasma formation is inhibited precluding a coating from being applied on the inner region 171A of substrate 102A. However, the increased distance (e.g., distance 135A) between the outer region 132A of first gas distribution plate 107A and the substrate 102A creates a larger volume where plasma ignition is not inhibited, resulting in plasma enhanced chemical vapor deposition on a target region near the edge of the substrate (e.g., outer region 172A of substrate 102A).

In some embodiments, the substrate support assembly 104A is configured to chuck the substrate 102A. For example, a substrate support pedestal of the substrate support assembly 104A can be configured to chuck the substrate 102A. In some embodiments, susceptor 122A of the substrate support assembly 104A can be configured to chuck the substrate 102A. This chucking mechanism can utilize one or more or vacuum or electrostatic chucking techniques to secure the substrate 102A in place. By chucking the substrate 102A, any potential bow in the substrate 102A can be corrected, resulting in a more uniform and concentric bevel deposition. Correcting the bow ensures that the substrate 102A lies flat, allowing for precise and consistent film thickness during the deposition process. In some embodiments, the chucking can correct bowing in a substrate that has up to 1 mm of bowing.

In some embodiments, a direct current chucking voltage of an electrostatic chuck is applied to the grounded substate support assembly 106A to securely hold the substrate 102A in place during processing. In some embodiments, RF filters are incorporated in the electrostatic chuck to isolate the direct current chucking power supply from incoming RF waves, preventing interference between the direct current and RF systems.

In some embodiments, the substrate support assembly (e.g., the pedestal of the substrate support assembly 104A) can be configured to rotate during a deposition process. In some embodiments, a rotation kit 170A of substrate support assembly 104A can be configured to allow one or more of the substrate support pedestal or susceptor 122A of substrate support assembly 104A to rotate during bevel deposition processes. By rotating one or more of the substrate support pedestal or susceptor 122A the substrate 102A is rotated, resulting in a more uniform and concentric bevel deposition.

Rotation kit 170A for substrate support assembly 104A can enable the controlled rotation of the substrate during processing. In some embodiments, rotation kit 170A can include components such as a motor and drive mechanism that connects to the substrate support pedestal or susceptor 122A, allowing the substrate 102A to be rotated at a specified rate. Rotating the substrate ensures even exposure to process gases and uniform application of concentric films (e.g., applied at or near the bevel of a substrate).

In some embodiments, rotary kit 170A allows at least a component (e.g., substrate support pedestal, susceptor 122A, etc.) of the substrate support to rotate during processing. In some embodiments, the rotation kit 170A can include a rotating feedthrough system, which integrates, for example, electrical, vacuum, heating, cooling connections, etc. The DC chucking voltage or vacuum suction, for securely holding the substrate in place, can be delivered through these rotating electrical feedthroughs, ensuring a continuous and stable connection even while the pedestal rotates cooling and heating systems can be connected through their respective rotating feedthroughs.

In some embodiments, the substrate support assembly 104A (e.g. support pedestal) can be configured to be vertically adjustable. This vertical adjustability allows for precise control over the distance between the substrate 102A and the first gas distribution plate 107A within the process volume 110A of process chamber 100A. By adjusting the height of the substrate support pedestal vertically, process parameters such as gas flow dynamics, plasma density, and deposition uniformity can be adjusted in order to cause the process gas to be concentrated at or near the outer region 172A of the substrate 102A. Additionally, vertical adjustability of the substrate support pedestal facilitates loading and unloading of substrates by lowering the pedestal to a loading/unloading height for substrate transfer, minimizing the risk of damage and ensuring efficient handling.

In some embodiments, the substrate support pedestal can be configured to actively maintain the substrate in a parallel orientation relative to the deposition surface (e.g., first gas distribution plate 107A) throughout the processing cycle (e.g., using dynamic planarity control). By adjusting the positioning and alignment of the substrate support pedestal, any tilting or warping of the wafer that may occur due to thermal expansion, mechanical stress, or other factors can be compensated for. By ensuring that the substrate remains level and parallel, the uniformity and precision of the deposition process is enhanced, leading to consistent film thickness and improved overall quality of the substrate.

In some embodiments, O rings 180A (e.g., elastomeric seals) can be disposed between first gas distribution plate 107A and second gas distribution plate 140A to ensure that process gases and purge gases do not mix before passing through first gas distribution plate 107A into processing volume 110A.

In some embodiments, manufacturing chamber 100A includes a remote plasma source (e.g., for cleaning purposes). This remote plasma source generates reactive plasma outside the main chamber and introduces it into the chamber to efficiently remove residues and contaminants from internal surfaces. Utilizing a remote plasma source for cleaning helps maintain chamber integrity and ensures consistent performance by preventing direct exposure of critical components to the plasma, extending their operational lifespan. In some embodiments, the remote plasma source supplies nitrogen trifluoride (NF₃) to remove residues and contaminants from the manufacturing chamber 100A. When activated by plasma, NF₃ decomposes into reactive fluorine species, which effectively break down and clean deposited films, particles, and other unwanted materials from the chamber surfaces.

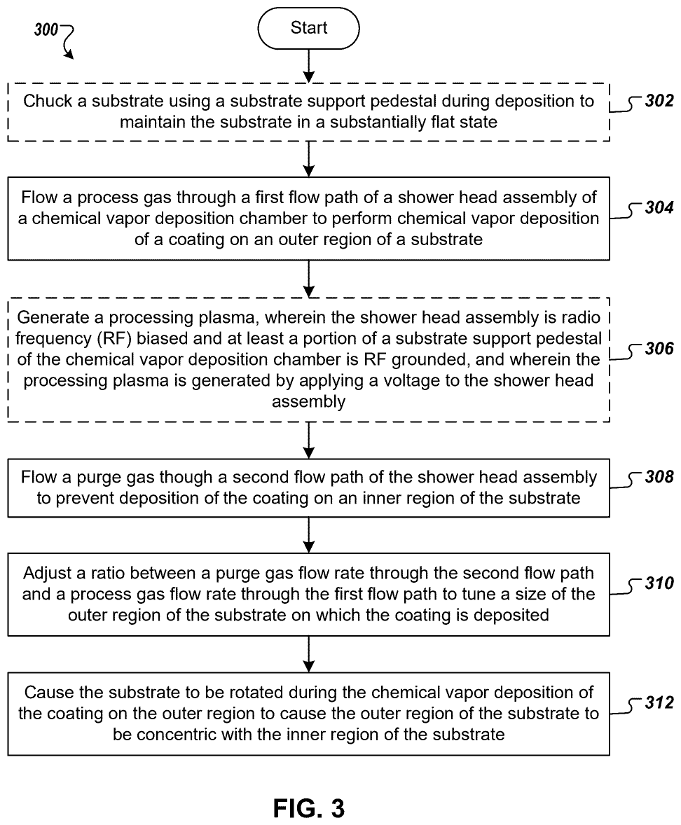

In embodiments, chamber 100A includes or is associated with a controller 190. Controller 190 may control various aspects of and/or associated with the chamber 100A, including the substrate support assembly 104A, heaters, gas delivery, plasma generators, and so on. The controller 190 may implement method 300 of FIG. 3 in embodiments. The controller 190 may be and/or include a computing device such as a personal computer, a server computer, a programmable logic controller (PLC), a microcontroller, and so on. The controller 109 may include one or more processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like.

Although not illustrated, the controller 190 may include a data storage device (e.g., one or more disk drives and/or solid state drives), a main memory, a static memory, a network interface, and/or other components. The controller 190 may execute instructions to perform any one or more of the methodologies and/or embodiments described herein. Instructions (e.g., a recipe) for bevel deposition may be stored on a computer readable storage medium, which may include the main memory, static memory, secondary storage and/or processing device (during execution of the instructions). Controller 190 may execute the recipe in embodiments to perform bevel deposition on a substrate.

FIG. 1B depicts a sectional view of a manufacturing chamber 100B (e.g., a plasma enhanced chemical vapor deposition chamber), according to some aspects of this disclosure. In some embodiments, manufacturing chamber 100B can be the same or a similar manufacturing chamber as manufacturing chamber 100A depicted in FIG. 1A.

In some embodiments, manufacturing chamber 100B includes a chamber body 108B and a showerhead assembly 106B that encloses an process volume 110B.

Shower head assembly 106B may include a first gas distribution plate 107B. First gas distribution plate 107B has an inner region 130B having a first radius (e.g., a first outer radius) and a first thickness 131B. The first thickness 131B causes the inner region 130B to be positioned a first distance 134B from a substrate 102B (e.g., supported by a substrate support assembly 104B). First gas distribution plate 107B includes an outer region 132B that is concentric with the inner region 130B, the outer region 132B having a second radius that is greater than the first radius. The outer region 132B further has a second thickness 133B that is less than the first thickness 131B. The second thickness 133B causes the outer region 132B to have a second distance 135B from the substrate 102B, the first distance 134B being less than the second distance 135B. The first gas distribution plate 107B is configured to deposit a coating on an outer region 172B of the substrate 102B while mitigating (e.g., preventing or minimizing) deposition of the coating on an inner region 171B of the substrate 102B. Accordingly, a coating on inner region 171B may be reduced or eliminated in embodiments. In some embodiments, the first gas distribution plate 107B is configured to deposit a coating on an outer region 172B of the substrate 102B without depositing the coating on an inner region 171B of the substrate 102B.

In some embodiments, the shower head assembly 106B can be RF biased and at least a portion of the substrate support assembly (e.g., susceptor 122B) is RF grounded. In some embodiments, process chamber 100B is a plasma-enhanced chemical vapor deposition chamber. In some embodiments, the shower head assembly 106B and the substrate support assembly 104B are configured to create a process plasma. For example, the showerhead assembly 106B can be configured as an RF-biased electrode, while at least a portion of the substrate support assembly 104B, such as the susceptor 122B, is RF-grounded. This configuration establishes an alternating electric field between the RF-biased showerhead assembly 104B and the RF-grounded susceptor 122B. As process gas is introduced through the showerhead assembly 106B into the process volume 110B, the alternating electric field ionizes the gas molecules, creating a plasma. The energetic ions and reactive species of the plasma enhance the chemical deposition reactions on the surface of substrate 102B, facilitating the formation of a uniform thin film.

In some embodiments, because inner region 130B is in close proximity to the substrate 102B, plasma formation is inhibited precluding a coating from being applied on the inner region 171B of substrate 102B. However, the increased distance (e.g., distance 135B) between the outer region 132B of first gas distribution plate 107B and the substrate 102B creates a larger volume where plasma ignition is not inhibited, resulting in plasma enhanced chemical vapor deposition on a target region near the edge of the substrate (e.g., outer region 172B of substrate 102B).

Showerhead assembly 106B may include multiple gas delivery holes throughout (e.g., on first gas distribution plate 107B and a second gas distribution plate 140B). In some embodiments, gas delivery holes are included in the inner region 130B and not the outer region 132B. Gas delivery holes located on the inner region 130B of the first gas distribution plate 107B are positioned directly above the substrate 102B. Gas delivery holes are not positioned above the outer region 172B of the substrate 102B where the recess in the shower head exists. In some embodiments, the process gas can be flowed through a flow path 162B and through the gas delivery holes. The process gas can flow in a radial direction towards the outer region 172B of the substrate 102B (e.g. a wafer bevel), where plasma will be ignited causing the coating to be applied on the outer region 172B of substrate 102B.

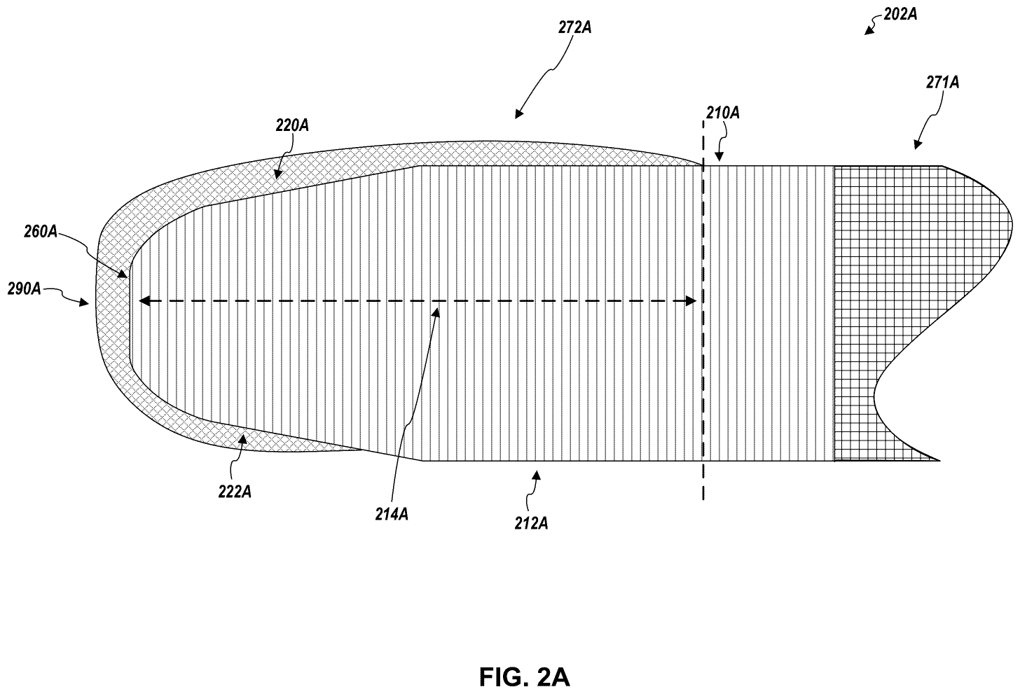

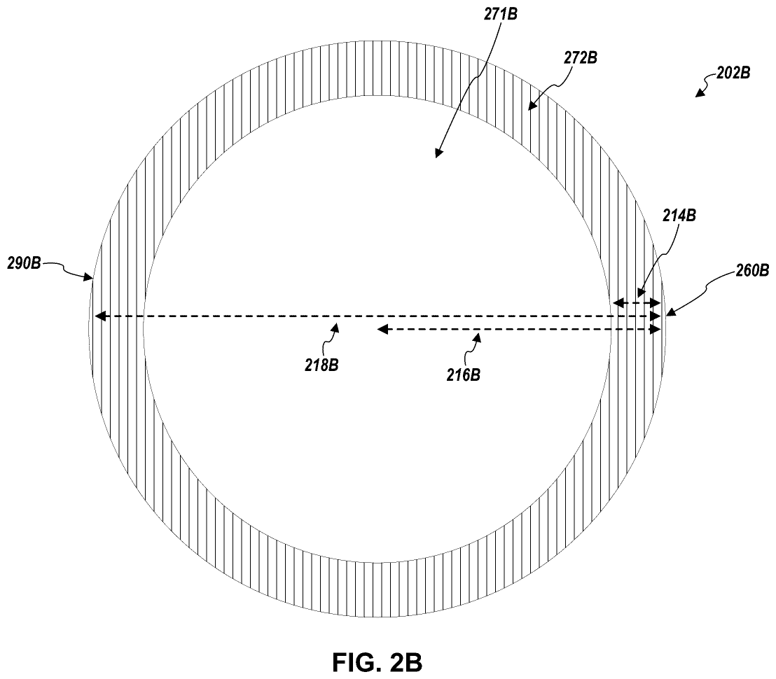

FIG. 2A depicts a cross-sectional side view of a bevel deposition of a substrate, according to some embodiments. In particular, FIG. 2A shows a cross-sectional side view of an outer edge of a substrate that includes a bevel.

In some embodiments, a substrate 202A is processed by a system for bevel deposition. For example, a process chamber (e.g., a plasma enhanced chemical vapor deposition chamber) including a substrate support assembly. The process chamber also includes a shower head assembly. The shower head assembly can be RF biased with at least a portion of the substrate support assembly being grounded. When a process gases is flowed through the shower head these RF biased components act as electrodes creating a process plasma that can enhance deposition efficiency and improve film quality.

The shower head assembly includes a first gas distribution plate (e.g., a faceplate) that has two regions with different thicknesses: an inner and outer region that are concentric (i.e., arranged around a common center). The difference in thickness allows for the inner region to be closer to a substrate 202A, while the outer region is farther away. When a process gas flows through the first gas distribution plate of the shower head during deposition, it selectively applies a coating 290A (e.g., a film) to the outer region 272A of the substrate 202A without depositing the coating 290A on an inner region 271A of the substrate 202A, or with reduced or minimal deposition of the coating 290A on the inner region 271A of the substrate 202A. In some embodiments, plasma formation can be inhibited in the inner region 271A due to the proximity of the first gas distribution plate to the substrate 202A. However, the increased distance between the outer region of the first gas distribution plate and the substrate 202A creates more space for plasma ignition, resulting in enhanced chemical vapor deposition on a target area near the edge of the substrate (e.g., outer region 272A of substrate 202A).

In some embodiments, coating 290A is applied to a frontside 210A of substrate 202A. The coating 290A can cover an frontside bevel 220A as well as a portion of the frontside of the substrate 202A. For example, a wafer having a diameter of 300 mm may have a coating applied to the bevel area of the substrate beginning at a radius ranging from 140 mm to 149 mm, 145 mm to 148 mm, or 143 mm to 147 mm and extending to the edge of the wafer 260A (e.g., a radius of 150 mm). In some embodiments, the coverage and thickness of the coating 290A can vary to accommodate different wafer sizes, such as 200 mm, 450 mm, or larger wafers. For instance, a 200 mm wafer might have coating applied starting from a radius of 90 mm to 98 mm and extending to the edge (e.g., a radius of 100 mm), while a 450 mm wafer might have coverage starting from a radius of 210 mm to 224 mm and extending to the edge (e.g., a radius of 225 mm). These examples illustrate that the coating can be tailored to fit various wafer sizes and application requirements.

In some embodiments, a thickness 214A of the coating 290A for a 300 mm wafer can be 2 mm to 5 mm. For smaller wafers, such as a 200 mm wafer, the coating thickness can range from, for example, 1 mm to 3 mm to accommodate the reduced surface area. Conversely, for larger wafers, such as a 450 mm wafer, the coating thickness can be, for example, to a range of 3 mm to 6 mm, ensuring adequate coverage and protection for the increased surface area. Additionally, the thickness 214A of the coating 290A, as well as the starting point of the coating, can be adjusted as appropriate to suit different applications and wafer sizes. This flexibility allows for the coating process to be tailored to various manufacturing requirements, ensuring optimal performance across a wide range of substrates and deposition scenarios.

In some embodiments, coating 290A can cover a backside bevel 222A of the substrate. The coating 290A does not cover the backside of the substrate 212A. Coating 290A is concentric to substrate 202A in some embodiments. In some embodiments, coating 290A is applied uniformly to the target deposition area centered on the center of substrate 202A, forming a uniform ring-like layer. Coating 290A is distributed in a circular pattern that is centered on the substrate.

FIG. 2B depicts a top view of a bevel deposition of a substrate, according to some embodiments.

In some embodiments, a substrate 202B is processed by a system for bevel deposition. For example, a process chamber (e.g., a plasma enhanced chemical vapor deposition chamber) including a substrate support assembly. The process chamber also includes a shower head assembly. The shower head assembly can be RF biased with at least a portion of the substrate support assembly being grounded. When a process gases is flowed through the shower head these RF biased components act as electrodes creating a process plasma that can enhance deposition efficiency and improve film quality.

The shower head assembly includes a first gas distribution plate (e.g., a faceplate) that has two regions with different thicknesses: an inner and outer region that are concentric (i.e., arranged around a common center). The difference in thickness allows for the inner region to be closer to a substrate 202B, while the outer region is farther away. When a process gas flows through the first gas distribution plate of the shower head during deposition, it selectively applies a coating 290B (e.g., a film) to the outer region 272B of the substrate 202B while mitigating deposition of the coating 290B on an inner region 271B (e.g., without depositing the coating 290B on an inner region 271B of the substrate 202B, or with reduced or minimal deposition of the coating 290B on the inner region 271B of the substrate 202B). In some embodiments, plasma formation can be inhibited in the inner region 271B due to the proximity of the first gas distribution plate to the substrate 202B. However, the increased distance between the outer region of the first gas distribution plate and the substrate 202B creates more space for plasma ignition, resulting in enhanced chemical vapor deposition on a target area near the edge of the substrate (e.g., outer region 272B of substrate 202B).

In some embodiments, coating 290B is applied to a frontside of substrate 202B. The coating 290B can cover an frontside bevel as well as a portion of the frontside of the substrate 202B. The coating 290B can cover the backside bevel of the substrate 202B.

FIG. 3 is a flow diagram of a method 300 associated with bevel deposition on a substrate, according to some embodiments. One or more operations of method 300 may be performed by a system (e.g., a bevel deposition system), which may include various components such as a process chamber, a substrate support assembly, a shower head assembly, a flow controller, etc. The system may utilize a combination of hardware elements such as first gas distribution plate, electrodes, shower heads, pedestals, etc., as well as control systems that regulate operational parameters to achieve a target deposition on the bevel of a substrate. In some embodiments, method 300 is performed, or caused to be performed, by a controller such as controller 190 of FIG. 1A.

For simplicity of explanation, method 300 is depicted and described as a series of operations. However, operations in accordance with this disclosure can occur in various orders and/or concurrently and with other operations not presented and described herein. Furthermore, not all illustrated operations may be performed to implement method 300 in accordance with the disclosed subject matter. In addition, those skilled in the art will understand and appreciate that method 300 could alternatively be represented as a series of interrelated states via a state diagram or events.

Referring to FIG. 3, in some embodiments, at block 302 the system implementing method 300A may chuck a substrate using a substrate support pedestal during a performance of a chemical vapor deposition to maintain the substrate in a substantially flat state.

At block 304, the system flows a process gas through a first flow path of a shower head assembly of a chemical vapor deposition chamber to perform chemical vapor deposition of a coating on an outer region of a substrate.

In some embodiments, the shower head assembly includes a first gas distribution plate (e.g., a faceplate) including the first flow path and the second flow path. The first gas distribution plate further includes an inner region of the first gas distribution plate having a first outer radius and a first thickness. The first thickness causes the inner region of the first gas distribution plate to have a first distance from the substrate. The first gas distribution plate further includes an outer region of the first gas distribution plate that is concentric with the inner region, the outer region of the first gas distribution plate having a first inner radius that corresponds to the first outer radius and a second outer radius that is greater than the first inner radius. The outer region further has a second thickness that is less than the first thickness. The second thickness causes the outer region to have a second distance from the substrate. The first distance is less than the second distance, causing the inner region to be closer to the substrate than the outer region.

In some embodiments, the configuration of the first gas distribution plate causes the coating to be deposited on the outer region of the substrate without being deposited on the inner region of the substrate, or with reduced or minimal deposition of the coating on the inner region of the substrate. For example, because inner region is in close proximity to the substrate (e.g., within 0.3 mm, 0.5 mm, 0.6 mm, 0.7 mm, and so on) plasma formation is inhibited precluding a coating from being applied on the inner region of the substrate. However, the greater distance between the outer region of first gas distribution plate and the substrate (e.g., within 3 mm to 5 mm, 2 mm to 4 mm, 4 mm to 6 mm, and so on) creates a larger volume where plasma ignition is not inhibited, resulting in plasma enhanced chemical vapor deposition on a target region near the edge of the substrate.

In some embodiments, the system can adjust a substrate support pedestal supporting the substrate in a vertical direction to adjust a distance between the substrate and the first gas distribution plate.

At block 306, the system may generate a processing plasma. The shower head assembly may be RF biased and at least a portion of a substrate support pedestal of the chemical vapor deposition chamber may be RF grounded. The processing plasma may be generated by applying a voltage to the shower head assembly while the process gas is flowed through the first flow path.

At block 308, the system flows a purge gas through a second flow path of the shower head assembly to prevent deposition of the coating on an inner region of the substrate.

At block 310, the system adjusts a ratio between a purge gas flow rate through the second flow path and a process gas flow rate through the first flow path to tune a size of the outer region of the substrate on which the coating is deposited. The bevel deposition may form a band of deposited material around the outer edge of the substrate. Increasing a flow of the purge gas relative to a flow of the process gas may reduce the width of the deposited band. Decreasing the flow of the purge gas relative to the flow of the process gas may increase the width of the deposited band.

At block 312, the system causes the substrate to be rotated during the chemical vapor deposition of the coating on the outer region to cause the outer region of the substrate to be concentric with the inner region of the substrate.

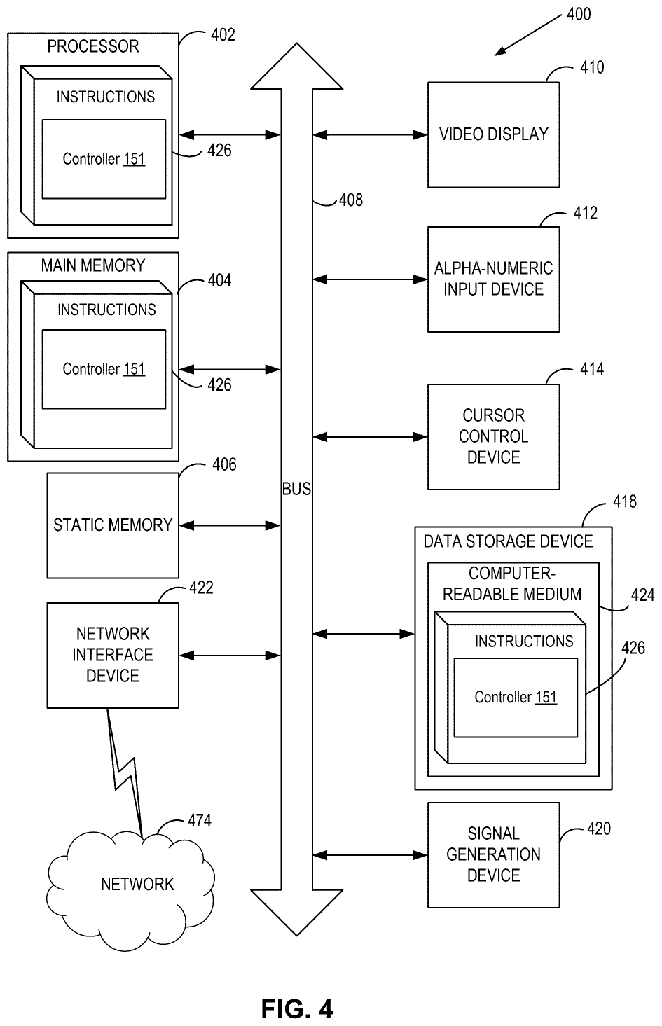

FIG. 4 is a block diagram illustrating a computer system 400, according to some embodiments. In some embodiments, computer system 400 may be connected (e.g., via a network, such as a Local Area Network (LAN), an intranet, an extranet, or the Internet) to other computer systems. Computer system 400 may operate in the capacity of a server or a client computer in a client-server environment, or as a peer computer in a peer-to-peer or distributed network environment. Computer system 400 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 400 may include a processing device 402, a volatile memory 404 (e.g., Random Access Memory (RAM)), a non-volatile memory 406 (e.g., Read-Only Memory (ROM) or Electrically-Erasable Programmable ROM (EEPROM)), and a data storage device 418, which may communicate with each other via a bus 408.

Processing device 402 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 400 may further include a network interface device 422 (e.g., coupled to network 474). Computer system 400 also may include a video display unit 410 (e.g., an LCD), an alphanumeric input device 412 (e.g., a keyboard), a cursor control device 414 (e.g., a mouse), and a signal generation device 420.

In some implementations, data storage device 418 may include a non-transitory computer-readable storage medium 424 (e.g., non-transitory machine-readable storage medium) on which may store instructions 426 encoding any one or more of the methods or functions described herein, including instructions encoding controller 151 and for implementing methods described herein.

Instructions 426 may also reside, completely or partially, within volatile memory 404 and/or within processing device 402 during execution thereof by computer system 400, hence, volatile memory 404 and processing device 402 may also constitute machine-readable storage media.

While computer-readable storage medium 424 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “flowing,” “adjusting,” “chucking,” “generating,” “determining,” “processing,” “forming,” “applying,” “causing,” “opening,” “closing,” “measuring,” “calculating,” “changing,” “receiving,” “performing,” “providing,” “obtaining,” “accessing,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A system comprising:
a process chamber;
a substrate support assembly disposed within a process volume of the process chamber to support a substrate; and
a shower head assembly disposed within the process volume of the process chamber and comprising:
a gas distribution plate comprising:
an inner region having a first radius and a first thickness, wherein the first thickness causes the inner region to have a first distance from the substrate; and
an outer region that is concentric with the inner region, the outer region having a second radius that is greater than the first radius, the outer region further having a second thickness that is less than the first thickness, wherein the second thickness causes the outer region to have a second distance from the substrate, wherein the first distance is less than the second distance;
wherein the gas distribution plate is configured to deposit a coating on an outer region of the substrate while mitigating deposition of the coating on an inner region of the substrate.

2. The system of claim 1, wherein the shower head assembly further comprises:
a first flow path configured to deliver a purge gas to the inner region of the substrate; and
a second flow path configured to deliver a process gas to the outer region of the substrate, wherein delivery of the purge gas to the inner region of the substrate prevents the process gas from entering the inner region of the substrate.

3. The system of claim 2, the shower head assembly further comprising a flow controller to:
adjust a ratio of a purge gas flow rate through the first flow path and a process gas flow rate through the second flow path to adjust a size of the outer region of the substrate on which the coating is deposited.

4. The system of claim 1, wherein the shower head assembly is radio frequency (RF) biased and at least a portion of the substrate support assembly is RF grounded.

5. The system of claim 4, wherein the shower head assembly and the substrate support assembly are configured to create a process plasma.

6. The system of claim 1, wherein the gas distribution plate is configured to deposit the coating on the outer region of the substrate without depositing the coating on the inner region of the substrate.

7. The system of claim 6, wherein the substrate support assembly is configured to chuck the substrate and to rotate during a deposition process.

8. The system of claim 1, wherein the substrate support assembly is configured to be vertically adjustable.

9. The system of claim 1, wherein the process chamber is a plasma enhanced chemical vapor deposition chamber.

10. A method comprising:
flowing a process gas through a first flow path of a shower head assembly of a chemical vapor deposition chamber to perform chemical vapor deposition of a coating on an outer region of a substrate; and
flowing a purge gas through a second flow path of the shower head assembly to mitigate deposition of the coating on an inner region of the substrate.

11. The method of claim 10, wherein the shower head assembly comprises a gas distribution plate comprising the first flow path and the second flow path, the gas distribution plate further comprising:
an inner region of the gas distribution plate having a first radius and a first thickness, wherein the first thickness causes the inner region of the gas distribution plate to have a first distance from the substrate; and
an outer region of the gas distribution plate that is concentric with the inner region, the outer region of the gas distribution plate having a second radius that is greater than the first radius, the outer region further having a second thickness that is less than the first thickness, wherein the second thickness causes the outer region to have a second distance from the substrate, wherein the first distance is less than the second distance;
wherein a configuration of the gas distribution plate causes the coating to be deposited on the outer region of the substrate without being deposited on the inner region of the substrate.

12. The method of claim 10, further comprising:
adjusting a ratio between a purge gas flow rate through the second flow path and a process gas flow rate through the first flow path to tune a size of the outer region of the substrate on which the coating is deposited.

13. The method of claim 10, further comprising:
chucking the substrate to maintain the substrate in a substantially flat state.

14. The method of claim 10, further comprising:
causing the substrate to be rotated during the chemical vapor deposition of the coating on the outer region to cause the outer region of the substrate to be concentric with the inner region of the substrate.

15. The method of claim 11, further comprising:
adjusting a substrate support pedestal supporting the substrate in a vertical direction to adjust a distance between the substrate and the gas distribution plate.

16. The method of claim 10, further comprising:
generating a processing plasma, wherein the shower head assembly is radio frequency (RF) biased and at least a portion of a substrate support pedestal of the chemical vapor deposition chamber is RF grounded, and wherein the processing plasma is generated by applying a voltage to the shower head assembly.

17. A system comprising:
a process chamber;
a substrate support assembly disposed within a process volume of the process chamber to support a substrate; and
a shower head assembly disposed within the process volume of the process chamber and comprising:
a gas distribution plate comprising:
an inner region having a first radius and a first thickness, wherein the first thickness causes the inner region to have a first distance from the substrate; and
an outer region that is concentric with the inner region, the outer region having a second radius that is greater than the first radius, the outer region further having a second thickness that is less than the first thickness, wherein the second thickness causes the outer region to have a second distance from the substrate, wherein the first distance is less than the second distance;
wherein the gas distribution plate comprising the inner region and the outer region is configured to deposit a coating on an outer region of the substrate without depositing the coating on an inner region of the substrate; and
a controller to:
cause a process gas to flow through a first flow path of the shower head assembly to perform chemical vapor deposition of a coating on an outer region of the substrate; and
cause a purge gas to flow through a second flow path of the shower head assembly to prevent deposition of the coating on an inner region of the substrate.

18. The system of claim 17, wherein the controller is further to:
adjust a ratio between a purge gas flow rate through the second flow path and a process gas flow rate through the first flow path to tune a size of the outer region of the substrate on which the coating is deposited.

19. The system of claim 17, wherein the controller is further to:
cause the substrate to be rotated during the chemical vapor deposition of the coating on the outer region to cause the outer region of the substrate to be concentric with the inner region of the substrate.

20. The system of claim 17, wherein the controller is further to:
adjust the substrate support assembly in a vertical direction to adjust a distance between the substrate and the gas distribution plate.
